(19) United States
(12) Patent Application Publication
(10) Pub. No.: US 2008/0102624 A1
(43) Pub. Date: May 1, 2008

(54) Method of fabricating semiconductor device with recess gate

(75) Inventors: Yong-Tae Cho, Kyoungki-do (KR); Suk-Ki Kim, Kyoungki-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX Semiconductor Inc.

(21) Appl. No.: 11/647,200

(22) Filed: Dec. 29, 2006

(30) Foreign Application Priority Data
Oct. 30, 2006 (KR) 10-2006-0105458

(51) Int. Cl. H01L 21/4763

(52) U.S. Cl. 438/639

(57) ABSTRACT

A method of fabricating a semiconductor device includes forming a hard mask pattern over a substrate, wherein the hard mask pattern exposes a recess region, performing a first etching process on the exposed recess region to form a first recess having sidewalls and to form passivation layers on the sidewalls of the first recess wherein the passivation layers are comprised of an etch reactant of the first etching process, and performing a second etching process on the substrate below the first recess to form a second recess.

### CROSS-REFERENCE TO RELATED APPLICATIONS

The present invention claims priority of Korean patent application number 10-2006-0105458, filed on Oct. 30, 2006, being incorporated by reference in its entirety.

### BACKGROUND

The present invention relates to a method of fabricating a semiconductor device, and more particularly, to a method of fabricating a semiconductor device with a recess gate.

As semiconductor devices have become highly integrated recently, occurrences of junction leakage has increased. The junction leakage is caused by a reduced channel length of cell transistors and an increased doping concentration for ion implantation of substrates, resulting in an increased electric field. Thus, it has become difficult to maintain a refresh characteristic of a device with a typical planar transistor structure.

To overcome such difficulty, a three-dimensional recess gate process has been introduced. The process includes etching a certain portion of an active region of a substrate to form a recess and forming a gate over the recess. Thus, the channel length of a cell transistor is increased and the doping concentration for ion implantation is decreased, improving the refresh characteristic.

FIG. 1 illustrates a cross-sectional view showing a typical method of fabricating a semiconductor device having a recess gate. Device isolation structures 12 are formed in a substrate 11. A patterned oxide layer 13 and a hard mask 14 are formed over the substrate structure. The patterned oxide layer 13 and the hard mask 14 expose portions of the substrate 11 predetermined for forming recesses. The substrate 11 is etched using the hard mask 14 as an etch mask to form the recesses having a vertical profile.

However, horns having a cuspidal shape may be formed during the typical method of forming a recess. That is, due to a recipe used during the process, e.g., a plasma etching process, a bottom portion of the recess pattern may obtain a sharp V-shaped profile. Accordingly, horns having the cuspidal shape may be formed at the border of recess patterns adjacent to device isolation structures. During a process for forming the device isolation structure, for example, a shallow trench isolation (STI) process, a STI angle becomes less than 90°, and thus, such horns are formed. The horns often become a concentration point for stress, increasing leakage current during operation of the device. Thus, the refresh characteristic of the device may deteriorate.

FIG. 2 illustrates a micrographic view of a profile of recess patterns and horns according to the typical method. The horns with a substantial height remain near device isolation regions. The horns may deteriorate the refresh characteristic of the device although the aforementioned recess gate process is introduced to improve the refresh characteristic of the device. Thus, a technology that can minimize the size of the horns and reduce leakage current may be needed.

### SUMMARY

Embodiments of the present invention are directed to provide a method of fabricating a semiconductor device having a recess gate, which can improve a refresh characteristic of the device by minimizing the size of horns generated during a recess formation process to reduce leakage current.

In accordance with some aspects of the present invention, there is provided a method of fabricating a semiconductor device, including: forming a hard mask pattern over a substrate, wherein the hard mask pattern exposes a recess region; performing a first etching process on the exposed recess region to form a first recess having sidewalls and to form passivation layers on the sidewalls of the first recess wherein the passivation layers are comprised of an etch reactant of the first etching process; and performing a second etching process on the substrate below the first recess to form a second recess.

### BRIEF DESCRIPTION OF THE DRAWINGS

FIG. 1 illustrates a cross-sectional view showing a typical method of fabricating a semiconductor device having a recess gate.

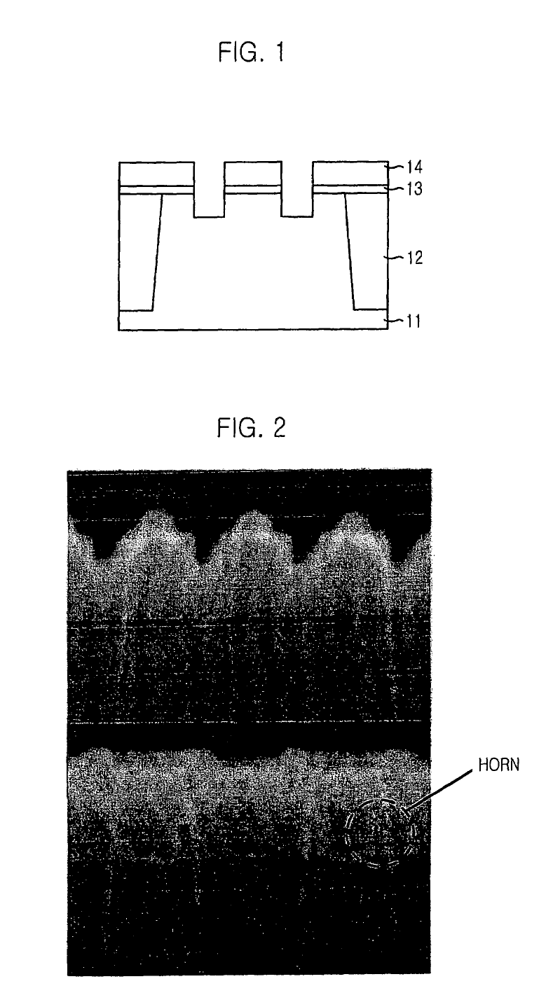

FIG. 2 illustrates a micrographic view of a profile of recess patterns and horns according to the typical method.

FIGS. 3A to 3E illustrate cross-sectional views showing a method of fabricating a semiconductor device having a recess gate in accordance with some embodiments of the present invention.

FIG. 4 illustrates a micrographic view of a profile of recess patterns and horns according to an embodiment of the present invention.

### DETAILED DESCRIPTION

The present invention relates to a method of fabricating a semiconductor device with a recess gate. According to some embodiments of the present invention, forming a recess having a dual profile, wherein profiles of a top portion and a bottom portion of the recess are different, allows minimizing the size of horns formed in a region adjacent to device isolation structures. Consequently, leakage current may be reduced and a refresh characteristic of the device may be improved. Thus, yield may improve and costs may decrease when fabricating the device.

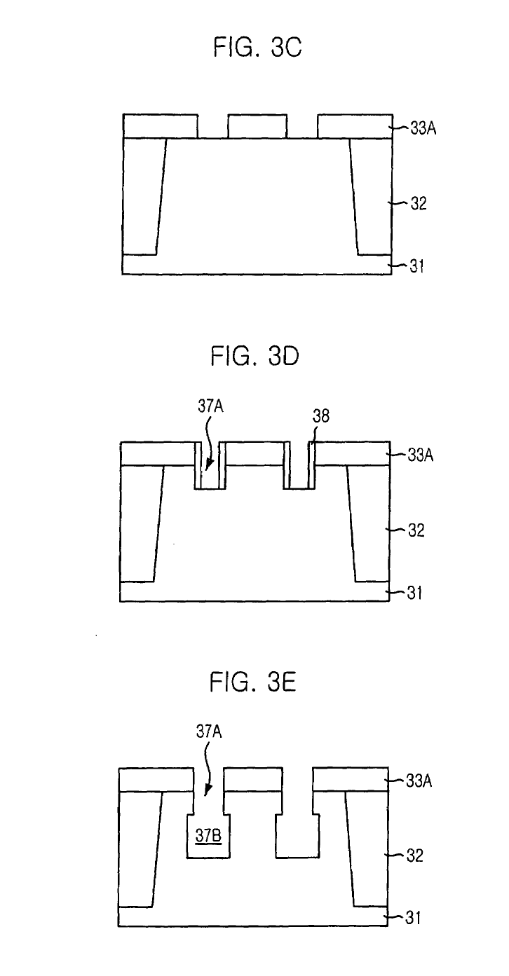

FIGS. 3A to 3E illustrate cross-sectional views showing a method of fabricating a semiconductor device having a recess gate in accordance with an embodiment of the present invention.

Referring to FIG. 3A, device isolation structures 32 are formed in a substrate 31. The device isolation structures 32 define an active region, and may be formed by employing a shallow trench isolation (STI) process. A first hard mask 33 and a second hard mask 34 are formed over the substrate 31 and the device isolation structures 32. The first hard mask 33 may include an oxide-based material and the second hard mask 34 may include amorphous carbon. The first hard mask 33 and the second hard mask 34 function as an etch barrier during a process for forming subsequent recesses. A photoresist pattern 36 is formed over the second hard mask 34. The photoresist pattern 36 exposes predetermined portions for forming the recesses. An anti-reflective coating layer 35 may be interposed below the photoresist pattern 36 to reduce reflection during a photo-exposure process.

Referring to FIGS. 3A and 3B, the second hard mask 34 and the first hard mask 33 are etched using the photoresist pattern 36 as an etch mask. Reference denotations 35A, 34A, and 33A refer to an anti-reflective coating pattern 35A, a second hard mask pattern 34A, and a first hard mask pattern 33A. In more detail, the second hard mask 34 is etched to expose portions of the first hard mask 33. The etching of the second hard mask 34 may use a magnetically enhanced reactive ion etching (MERIE) as a plasma source and a gas mixture including nitrogen (N₂) and oxygen (O₂). The first hard mask 33 is etched to expose portions of the substrate 31. The etching of the first hard mask 33 may use a gas mixture including CF_{X}/CHF_{Y}/O₂.

Referring to FIGS. 3B and 3C, the photoresist pattern 36 and the anti-reflective coating pattern 35A are removed. The second hard mask pattern 34A is then removed. The second hard mask pattern 34A may be removed using O₂ plasma solely and supplying a source power. A bias power is not supplied herein. A flow rate of the O₂ plasma may range from approximately 200 sccm to approximately 1,000 sccm.

Referring to FIG. 3D, a first etching process is performed on the substrate 31 to form first recesses 37A using the first hard mask pattern 33A as an etch barrier. The first etching process for forming the first recesses 37A may include using transformer coupled plasma (TCP)/inductively coupled plasma (ICP) as a plasma source and using a gas mixture comprising a major etch gas of hydrogen bromide (HBr) and an additive gas of CF_{X}H_{Y}. A recipe of the first etching process may include a pressure ranging from approximately 2 mTorr to approximately 20 mTorr, a source power ranging from approximately 700 W to approximately 1,500 W, and a bias power ranging from approximately 200 W to approximately 500 W. Using the aforementioned recipe allows obtaining the first recesses 37A having a vertical profile and a depth ranging from approximately 200 Å to approximately 500 Å.

During the first etching process for forming the first recesses 37A, polymers are formed on etched surfaces, especially on sidewalls of the first recesses 37A, as an etch reactant due to the CF_{X}H_{Y} gas. Such polymers are referred to as passivation layers 38 hereinafter. The passivation layers 38 function as an etch barrier during a process for forming subsequent second recesses. An abundant amount of polymers may be generated since the amorphous carbon layer is formed as the second hard mask 34 and the etch gas including the CF_{X}H_{Y} gas is used. When the CF_{X}H_{Y} gas is added to the etch gas used during the first etching process for forming the first recesses 37A and the formation process of the passivation layers 38, the CF_{X}H_{Y} gas may include one of fluoroform (CHF₃) gas and difluoromethane (CH₂F₂) gas.

Referring to FIG. 3E, a second etching process is performed on the substrate 31 to form second recesses 37B using the first hard mask pattern 33A and the passivation layers 38 (see FIG. 3D) as an etch barrier. The second etching process may be performed in-situ. The second etching process for forming the second recesses 37B may include using TCP/ICP as a plasma source and using a gas mixture comprising a chlorine-based gas and a bromine-based gas. A recipe of the second etching process may include a pressure ranging from approximately 10 mTorr to approximately 30 mTorr, a source power ranging from approximately 500 W to approximately 1,000 W, and a bias power ranging from approximately 200 W to approximately 500 W. When using HBr as the bromine-based gas and chlorine (Cl₂) as the chlorine-based gas, a flow rate ratio of HBr to Cl₂ may range from approximately 0.5 to approximately 2:1. The second etching process is performed on the substrate 31 with a slight isotropic etch characteristic using the aforementioned recipe. Thus, the second recesses 37B may be formed with a bowed profile, wherein sidewalls of the second recesses 37B are bowed inwardly, and to a depth ranging from approximately 700 Å to approximately 1,000 Å.

The first recesses 37A and the second recesses 37B configure intended recesses having a dual profile. The dual profile refers to having a top portion and a bottom portion of a recess with different profiles to each other. The bottom portion of the intended recesses having the dual profile has a width larger than that of a typical recess by several tens of nanometers (nm).

Although not shown, a third etching process may be performed to widen the width of the bottom portion of the intended recesses after forming the second recesses 37B. The third etching process uses the first hard mask pattern 33A and the passivation layers 38 as an etch barrier. Resulting in the second recesses 37B being widened sideways. The third etching process may include using TCP/ICP as a plasma source and using a gas comprising a mixed gas of HBr/Cl₂ and a mixed gas of sulfur hexafluoride (SF₆)/O₂. A recipe of the third etching process may include a pressure ranging from approximately 20 mTorr to approximately 100 mTorr, a source power ranging from approximately 500 W to approximately 1,500 W, and a bias power of approximately 50 W or less. An NF_{X} gas or a CF_{X} gas may be used instead of the SF₆ gas. The third etching process is performed on the substrate 31 with an isotropic etch characteristic using the aforementioned recipe. Thus, the second recesses 37B may be widened sideways by approximately 10 nm to approximately 15 nm. The size of horns may be further decreased by performing the third etching process. Although not shown, the first hard mask pattern 33A is removed and a process for forming recess gate patterns is performed.

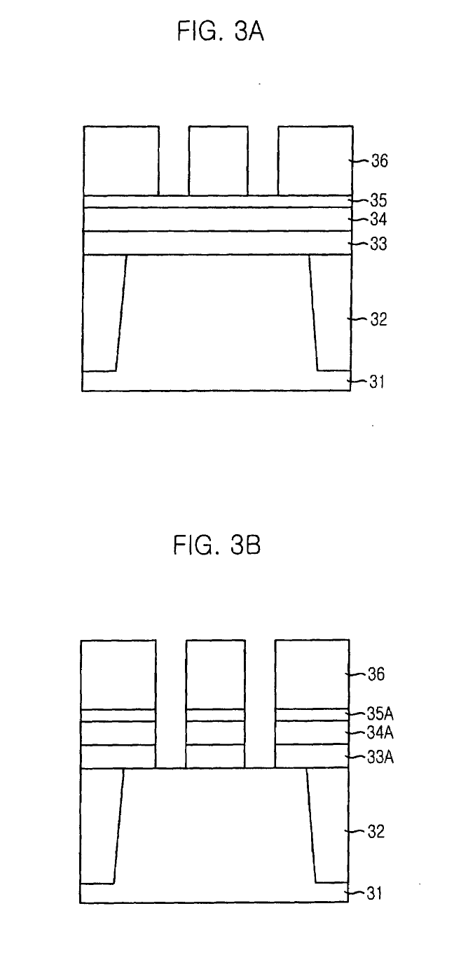

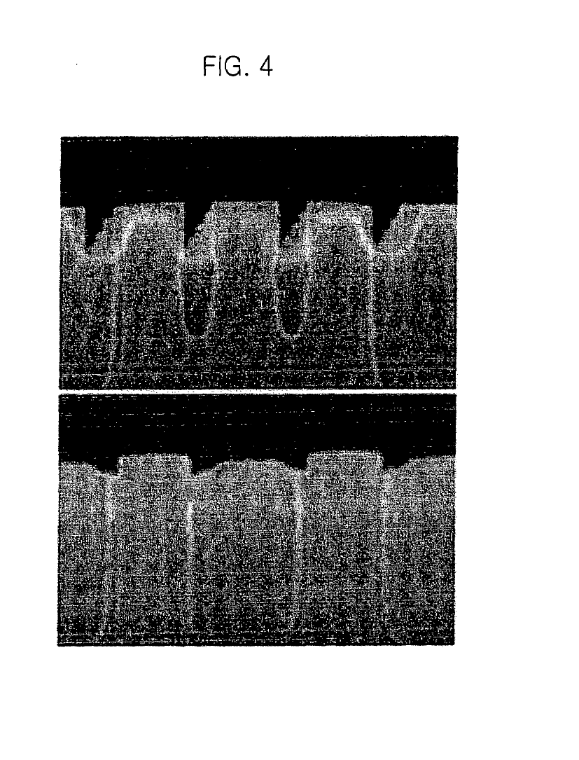

FIG. 4 illustrates a micrographic view of a profile of recess patterns and horns according to some embodiments of the present invention. The size of the horns is substantially decreased when compared to the typical method (refer to FIG. 2). Also, the recess patterns according to this embodiment have a dual profile instead of the sharp profile of the typical recess patterns. That is, the size of the horns may be minimized even when a STI angle becomes less than approximately 90°. Such recess patterns with the dual profile may decrease leakage current and improve a refresh characteristic. Thus, yield may increase and costs may decrease when fabricating the devices.

In some of the disclosed embodiments, the first, second, and third etching processes are performed in a high density etch apparatus using TCP/ICP as the plasma source, but in some alternative embodiments, the first, second, or third etching processes may be performed in an ICP type etch apparatus attached with a faraday shield. Further, in some alternative embodiments, the first, second, or third etching processes may be performed in an etch apparatus using a plasma source selected from a group consisting of microwave down stream (MDS), electron cyclotron resonance (ECR), and helical.

While the present invention has been described with respect to some embodiments, it will be apparent to those skilled in the art that various changes and modifications may be made without departing from the spirit and scope of the invention as defined in the following claims.

What is claimed is:

1. A method of fabricating a semiconductor device, comprising:
forming a hard mask pattern over a substrate, wherein the hard mask pattern exposes a recess region;
performing a first etching process on the exposed recess region to form a first recess having sidewalls and to form passivation layers on the sidewalls of the first recess wherein the passivation layers are comprised of an etch reactant of the first etching process; and
performing a second etching process on the substrate below the first recess to form a second recess.

2. The method of claim 1, further comprising performing a third etching process to widen the second recess sideways.

3. The method of claim 1, wherein forming the hard mask pattern further comprises forming the hard mask pattern comprising an oxide-based layer and an amorphous carbon layer.

4. The method of claim 3, wherein performing the first etching process further comprises:
removing the amorphous carbon layer from the hard mask pattern; and
performing the first etching process on the exposed recess region using the oxide-based layer of the hard mask pattern as an etch barrier.

5. The method of claim 4, wherein removing the amorphous carbon layer further comprises using oxygen (O₂) plasma at a flow rate ranging from approximately 200 sccm to approximately 1,000 sccm and supplying a predetermined amount of a source power.

6. The method of claim 1, wherein performing the first etching process further comprises using a gas including hydrogen bromide (HBr) and CF_{X}H_{Y}.

7. The method of claim 6, wherein CF_{X}H_{Y} comprises one of fluoroform (CHF₃) and difluoromethane (CH₂F₂).

8. The method of claim 6, wherein performing the first etching process further comprises using a pressure ranging from approximately 2 mTorr to approximately 20 mTorr, using a source power ranging from approximately 700 W to approximately 1,500 W, and using a bias power ranging from approximately 200 W to approximately 500 W.

9. The method of claim 1, wherein performing the second etching process further comprises using a gas including a bromine-based gas and a chlorine-based gas.

10. The method of claim 9, wherein performing the second etching process further comprises using the bromine-based gas comprising HBr and using the chlorine-based gas comprising chlorine (Cl₂).

11. The method of claim 10, wherein performing the second etching process further comprises using a flow rate ratio of HBr to Cl₂ ranging between approximately 0.5 to approximately 2:1.

12. The method of claim 9, wherein performing the second etching process further comprises using a pressure ranging from approximately 10 mTorr to approximately 30 mTorr, using a source power ranging from approximately 500 W to approximately 1,000 W, and using a bias power ranging from approximately 200 W to approximately 500 W.

13. The method of claim 2, wherein performing the third etching process further comprises using a gas including a gas mixture of HBr and Cl₂ and a gas mixture of sulfur hexafluoride (SF₆) and O₂.

14. The method of claim 13, wherein performing the third etching process further comprises using a gas including a gas mixture of HBr and Cl₂ and a gas mixture of O₂ and one of a NF_{X} gas and a CF_{Y} gas.

15. The method of claim 13, wherein performing the third etching process further comprises using a pressure ranging from approximately 20 mTorr to approximately 100 mTorr, using a source power ranging from approximately 500 W to approximately 1,500 W, and using a bias power of approximately 50 W or less.

16. The method of claim 1, wherein performing the first etching process and performing the second etching process further comprises performing the first etching process and performing the second etching process in-situ in a high density etch apparatus.

17. The method of claim 16, wherein the high density etch apparatus comprises a plasma source selected from the group consisting of transformer coupled plasma (TCP), inductively coupled plasma (ICP), microwave down stream (MDS), electron cyclotron resonance (ECR), and helical.

18. The method of claim 1, wherein performing the first etching process further comprises using the hard mask pattern as an etch barrier.

19. The method of claim 1, wherein performing the second etching process further comprises using the passivation layers as an etch barrier.

20. The method of claim 1, wherein performing the second etching process further comprises performing the second etching process on the substrate below the first recess to form a second recess having a bowed profile.
